(19) United States
(12) Patent Application Publication
(10) Pub. No.: US 2023/0418988 A1
(43) Pub. Date: Dec. 28, 2023

(54) ROOM MANAGEMENT SYSTEM, ROOM MANAGEMENT METHOD, AND COMPUTER READABLE MEDIUM

(71) Applicant: Mitsubishi Electric Corporation, Tokyo (JP)

(72) Inventors: Shinichiro OTANI, Tokyo (JP); Jin KAWASAKI, Tokyo (JP)

(73) Assignee: Mitsubishi Electric Corporation, Tokyo (JP)

(21) Appl. No.: 18/242,600

(22) Filed: Sep. 6, 2023

Related U.S. Application Data
(63) Continuation of application No. PCT/JP2021/016099, filed on Apr. 20, 2021.

(51) Int. Cl. G06F 30/13; G06Q 50/26

(52) U.S. Cl. CPC G06F 30/13; G06Q 50/265

(57) ABSTRACT

A number-of-allowable-users calculation unit (212) calculates, as the number of allowable users of a room, the number of persons with which a distance equal to or greater than a limit distance can be secured in the room, based on limit distance data indicating the limit distance defined as a distance to be kept between persons and room data indicating information on the room to be used by one or more persons.

### CROSS REFERENCE TO RELATED APPLICATIONS

This application is a Continuation of PCT International Application No. PCT/JP2021/016099, filed on Apr. 20, 2021, which is hereby expressly incorporated by reference into the present application.

### TECHNICAL FIELD

The present disclosure relates to room management for preventing the spread of infection.

### BACKGROUND ART

Companies implement business continuity planning (BCP) so that important operations will not be interrupted even if a disaster occurs.

In a building management system that supports BCP, business is continued using only available equipment in a situation where part of a building cannot be used due to a disaster such an earthquake, a fire, or a flood.

On the other hand, in a disaster such as an explosion of infection, the building can be used as usual. However, in order to prevent the spread of infection, it is necessary to create a work attendance plan and an equipment operation plan so as to prevent contact between employees.

Patent Literature 1 discloses calculating the maximum number of seats in a room, taking into consideration furniture such as desks and chairs and obstacles such as pillars.

However, Patent Literature 1 neither discloses nor suggests taking into consideration a distance that should be kept between persons.

Therefore, the description of Patent Literature 1 cannot be directly utilized for countermeasures against infection.

### CITATION LIST

### Patent Literature

Patent Literature 1: JP 2019-204254 A

### SUMMARY OF INVENTION

### Technical Problem

An object of the present disclosure is to make it possible to perform room management while preventing the spread of infection.

### Solution to Problem

A room management system of the present disclosure includes a number-of-allowable-users calculation unit to calculate, as the number of allowable users of a room, the number of persons with which a distance equal to or greater than a limit distance can be secured in the room, based on limit distance data indicating the limit distance defined as a distance to be kept between persons and room data indicating information on the room to be used by one or more persons.

### Advantageous Effects of Invention

According to the present disclosure, the number of allowable users of a room can be calculated taking into consideration a distance that should be kept between persons. Therefore, room management can be performed while preventing the spread of infection.

### BRIEF DESCRIPTION OF DRAWINGS

FIG. 1 is a configuration diagram of a room management system 100 in Embodiment 1;

FIG. 2 is a functional configuration diagram of the room management system 100 in Embodiment 1;

FIG. 3 is a flowchart of a room management method in Embodiment 1;

FIG. 4 is a flowchart of step S120 in Embodiment 1;

FIG. 5 is a diagram illustrating an overview of disclosure in Embodiment 1;

FIG. 6 is a functional configuration diagram of the room management system 100 in Embodiment 2;

FIG. 7 is a flowchart of a room management method in Embodiment 2;

FIG. 8 is a flowchart of step S220 in Embodiment 2;

FIG. 9 is a diagram illustrating an overview of disclosure in Embodiment 2;

FIG. 10 is a functional configuration diagram of the room management system 100 in Embodiment 3;

FIG. 11 is a flowchart of a room management method in Embodiment 3;

FIG. 12 is a flowchart of step S320 in Embodiment 3;

FIG. 13 is a diagram illustrating an overview of disclosure in Embodiment 3;

FIG. 14 is a configuration diagram of the room management system 100 in Embodiment 4;

FIG. 15 is a functional configuration diagram of the room management system 100 in Embodiment 4;

FIG. 16 is a flowchart of a room management method in Embodiment 4;

FIG. 17 is a flowchart of step S430 in Embodiment 4;

FIG. 18 is a configuration diagram of the room management system 100 in Embodiment 5;

FIG. 19 is a functional configuration diagram of the room management system 100 in Embodiment 5;

FIG. 20 is a flowchart of a room management method in Embodiment 5;

FIG. 21 is a flowchart of step S530 in Embodiment 5;

FIG. 22 is a flowchart of step S540 in Embodiment 5;

FIG. 23 is a configuration diagram of the room management system 100 in Embodiment 6;

FIG. 24 is a configuration diagram of an access control system 300 in Embodiment 6;

FIG. 25 is a functional configuration diagram of the room management system 100 in Embodiment 6;

FIG. 26 is a flowchart of a room management method in Embodiment 6;

FIG. 27 is a configuration diagram of the room management system 100 in Embodiment 7;

FIG. 28 is a configuration diagram of an access control system 400 in Embodiment 7;

FIG. 29 is a functional configuration diagram of the room management system 100 in Embodiment 7;

FIG. 30 is a flowchart of a room management method in Embodiment 7;

FIG. 31 is a flowchart of step S740 in Embodiment 7;

FIG. 32 is a configuration diagram of the room management system 100 in Embodiment 8;

FIG. 33 is a configuration diagram of an access control system 500 in Embodiment 8;

FIG. 34 is a functional configuration diagram of the room management system 100 in Embodiment 8;

FIG. 35 is a flowchart of a room management method in Embodiment 8;

FIG. 36 is a diagram illustrating an overview of disclosure in Embodiment 8; and

FIG. 37 is a hardware configuration diagram of a room management device 200 in the embodiments.

### DESCRIPTION OF EMBODIMENTS

In the embodiments and drawings, the same elements or corresponding elements are denoted by the same reference sign. Description of an element denoted by the same reference sign as that of an element that has been described will be suitably omitted or simplified. Arrows in diagrams mainly indicate flows of data or flows of processing.

### Embodiment 1

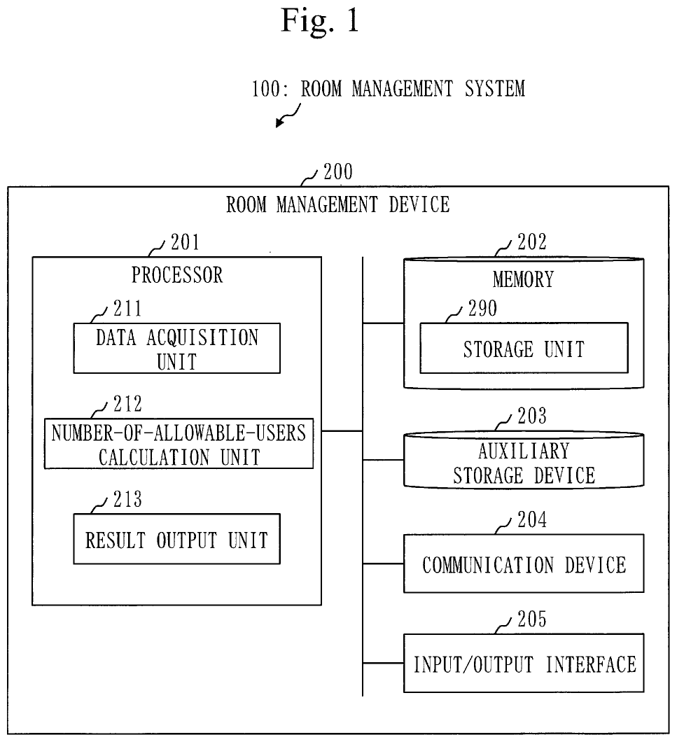

An embodiment in which the number of persons who can use a room is automatically calculated in a situation where a certain distance must be kept between persons will be described based on FIGS. 1 to 5.

### Description of Configuration

Based on FIG. 1, a configuration of a room management system 100 will be described.

The room management system 100 includes a room management device 200.

However, the room management system 100 may be realized by two or more devices (or systems).

The room management device 200 is a computer that includes hardware such as a processor 201, a memory 202, an auxiliary storage device 203, a communication device 204, and an input/output interface 205. These hardware components are connected with one another through signal lines.

The processor 201 is an IC that performs operational processing and controls other hardware components. For example, the processor 201 is a CPU, a DSP, or a GPU.

IC is an abbreviation for integrated circuit.

CPU is an abbreviation for central processing unit.

DSP is an abbreviation for digital signal processor.

GPU is an abbreviation for graphics processing unit.

The memory 202 is a volatile or non-volatile storage device. The memory 202 is also called a main storage device or a main memory. For example, the memory 202 is a RAM. Data stored in the memory 202 is saved in the auxiliary storage device 203 as necessary.

RAM is an abbreviation for random access memory.

The auxiliary storage device 203 is a non-volatile storage device. For example, the auxiliary storage device 203 is a ROM, an HDD, or a flash memory. Data stored in the auxiliary storage device 203 is loaded into the memory 202 as necessary.

ROM is an abbreviation for read only memory.

HDD is an abbreviation for hard disk drive.

The communication device 204 is a receiver and a transmitter. For example, the communication device 204 is a communication chip or a NIC. Communication of the room management device 200 is performed using the communication device 204.

NIC is an abbreviation for network interface card.

The input/output interface 205 is a port to which an input device and an output device are connected. For example, the input/output interface 205 is a USB terminal, the input device is a keyboard and a mouse, and the output device is a display. Input to and output from the room management device 200 is performed using the input/output interface 205.

USB is an abbreviation for Universal Serial Bus.

The room management device 200 includes elements such as a data acquisition unit 211, a number-of-allowable-users calculation unit 212, and a result output unit 213. These elements are realized by software.

The auxiliary storage device 203 stores a room management program to cause a computer to function as the data acquisition unit 211, the number-of-allowable-users calculation unit 212, and the result output unit 213. The room management program is loaded into the memory 202 and executed by the processor 201.

The auxiliary storage device 203 further stores an OS. At least part of the OS is loaded into the memory 202 and executed by the processor 201.

The processor 201 executes the room management program while executing the OS.

OS is an abbreviation for operating system.

Input data and output data of the room management program are stored in a storage unit 290.

The memory 202 functions as the storage unit 290. However, a storage device such as the auxiliary storage device 203, a register in the processor 201, and a cache memory in the processor 201 may function as the storage unit 290 in place of the memory 202 or together with the memory 202.

The room management device 200 may include a plurality of processors as an alternative to the processor 201.

The room management program can be recorded (stored) in a computer readable format in a non-volatile recording medium such as an optical disc or a flash memory.

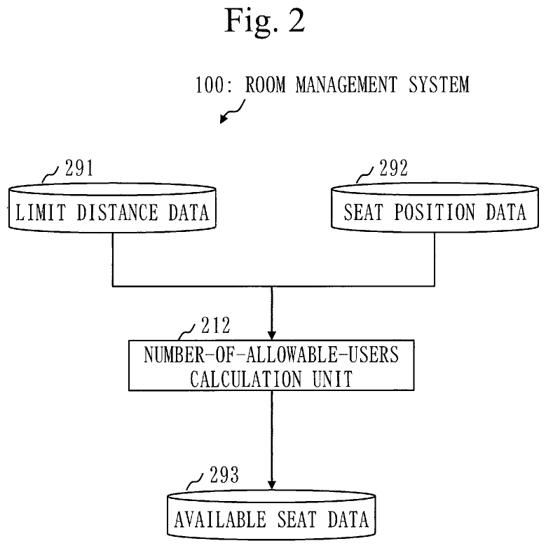

FIG. 2 illustrates a main functional configuration of the room management system 100. An arrow in the diagram indicates a flow of data or a flow of processing.

The operation of each element and the content of each piece of data in the room management system 100 will be described later.

### Description of Operation

A procedure for operation of the room management system 100 is equivalent to a room management method. The procedure for operation of the room management system 100 (mainly operation of the room management device 200) is equivalent to a procedure for processing by the room management program.

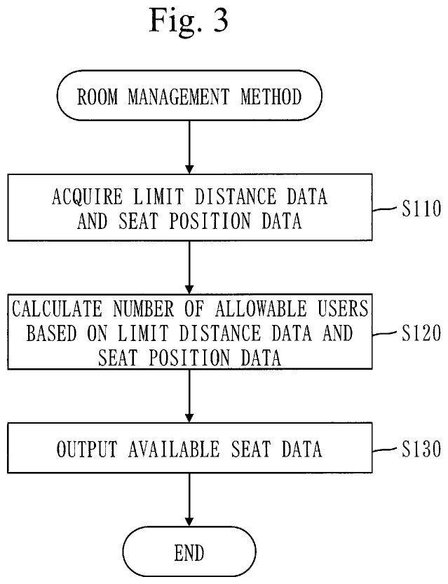

Based on FIG. 3, a room management method will be described.

In step S110, the data acquisition unit 211 acquires limit distance data 291 and seat position data 292.

For example, an administrator inputs the limit distance data 291 and the seat position data 292 to the room management device 200, and the data acquisition unit 211 accepts the limit distance data 291 and the seat position data 292 that are input.

The limit distance data 291 indicates a limit distance. The limit distance is equivalent to a distance called a social distance or a physical distance.

The limit distance is defined as the distance that must be kept between persons.

The seat position data 292 is an example of data indicating information on a room to be used by one or more persons (room data). A plurality of seats are placed in the room.

The seat position data 292 indicates the position of each of the plurality of seats in the room.

A specific example of a target room is a room in a company. A specific example of a user of the room is an employee.

In step S120, the number-of-allowable-users calculation unit 212 calculates the number of allowable users of the room based on the limit distance data 291 and the seat position data 292.

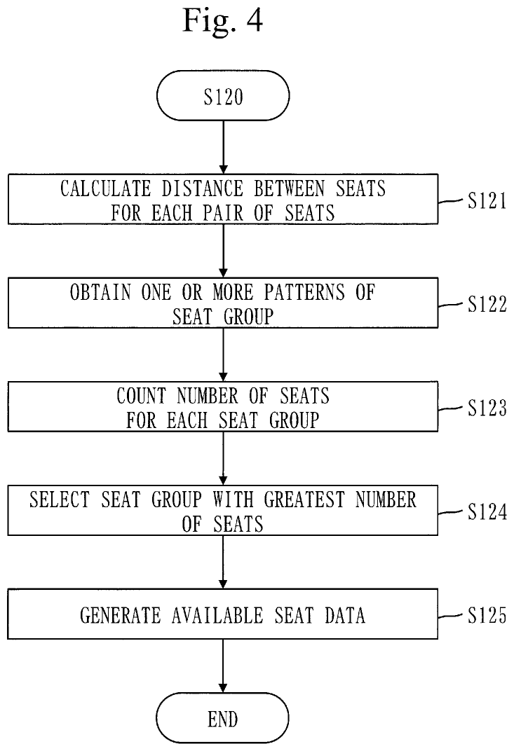

Based on FIG. 4, a procedure for step S120 will be described.

In step S121, the number-of-allowable-users calculation unit 212 calculates a distance between seats for each pair of seats in the room based on the positions of the seats indicated in the seat position data 292.

In step S122, the number-of-allowable-users calculation unit 212 obtains one or more patterns of a seat group based on the calculated distances between seats.

A seat group is composed of two or more seats between which a distance equal to or greater than the limit distance is secured. That is, in a seat group, every distance between seats is equal to or greater than the limit distance.

A seat group is obtained by any method. For example, a seat group is obtained by a solution algorithm for a three-color problem.

In step S123, the number-of-allowable-users calculation unit 212 counts the number of seats for each seat group.

In step S124, the number-of-allowable-users calculation unit 212 selects a seat group with the greatest number of seats.

In step S125, the number-of-allowable-users calculation unit 212 generates available seat data 293 based on the selected seat group.

The available seat data 293 indicates the number of allowable users and two or more available seats.

The number of allowable users corresponds to the number of seats in the selected seat group.

The two or more available seats are two or more seats constituting the selected seat group.

Referring back to FIG. 3, step S130 will be described.

In step S130, the result output unit 213 outputs the available seat data 293.

For example, the result output unit 213 displays the number of allowable users and the two or more available seats on a display.

### Features of Embodiment 1

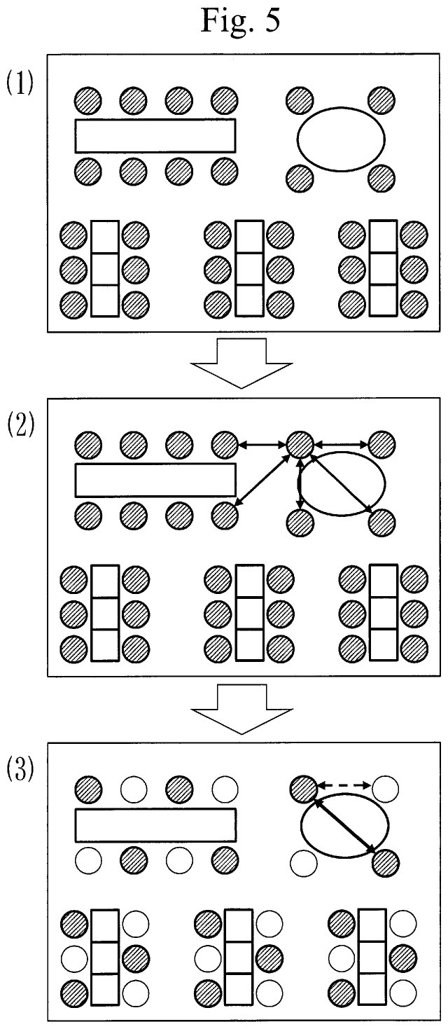

Based on FIG. 5, the features of Embodiment 1 will be described. A square frame represents a room.

(1) The data acquisition unit 211 acquires the seat position data 292. Each shaded circle represents a seat.

(2) The number-of-allowable-users calculation unit 212 calculates a distance between seats for each of all pairs of seats. A double-headed arrow represents a distance between seats.

(3) The number-of-allowable-users calculation unit 212 obtains a seat group in which a distance equal to or greater than the limit distance is secured and which has the maximum number of seats. Each seat belonging to the obtained seat group is an available seat. A dashed double-headed arrow represents a distance between seats that is less than the limit distance. A solid double-headed arrow represents a distance between seats that is equal to or greater than the limit distance. Each shaded circle represents an available seat. Each blank circle represents an unavailable seat.

### Effects of Embodiment 1

With Embodiment 1, the number of persons who can use a room can be automatically calculated in a situation where a certain distance must be kept between persons for a reason such as prevention of the spread of infection.

### Embodiment 2

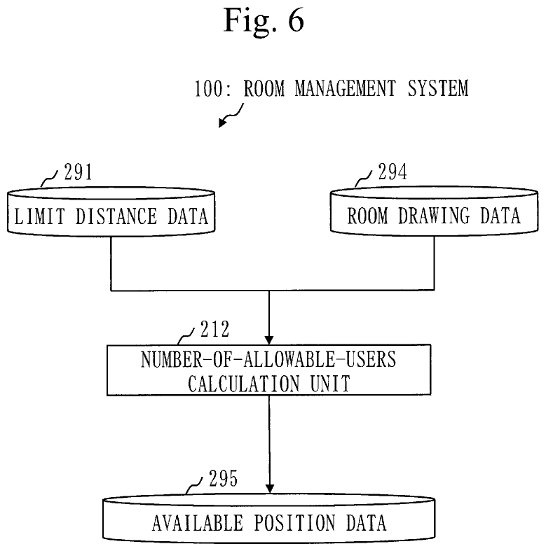

With regard to an embodiment in a case where the seat position data 292 cannot be obtained, differences from Embodiment 1 will be mainly described based on FIGS. 6 to 9.

### Description of Configuration

The configuration of the room management system 100 is the same as the configuration in Embodiment 1. However, room data that is different from the seat position data 292 is used.

FIG. 6 illustrates a main functional configuration of the room management system 100.

The operation of each element and the content of each piece of data in the room management system 100 will be described later.

### Description of Operation

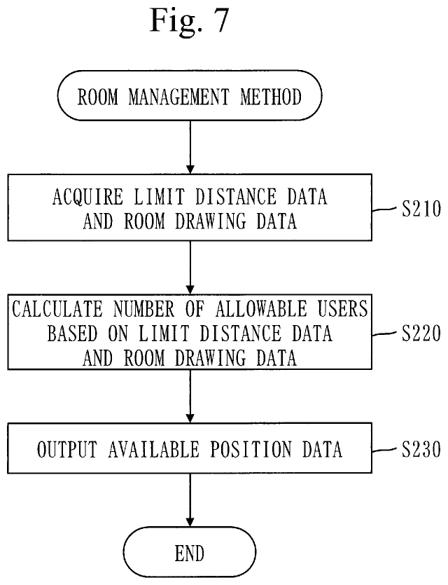

Based on FIG. 7, a room management method will be described.

In step S210, the data acquisition unit 211 acquires the limit distance data 291 and room drawing data 294.

The method of acquirement is the same as the method in step S110 of Embodiment 1.

The room drawing data 294 is an example of room data.

The room drawing data 294 represents a drawing of a room.

The drawing of the room indicates the shape of the room, the size of the room, and so on.

In step S220, the number-of-allowable-users calculation unit 212 calculates the number of allowable users of the room based on the limit distance data 291 and the room drawing data 294.

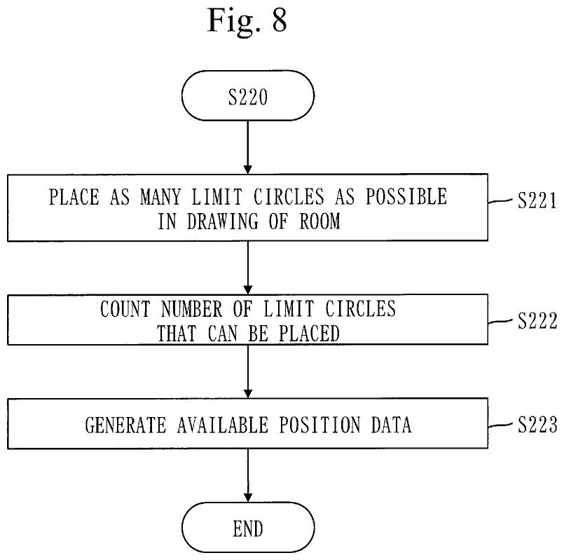

Based on FIG. 8, a procedure for step S220 will be described.

In step S221, the number-of-allowable-users calculation unit 212 places as many limit circles as possible in the drawing of the room so as to avoid overlapping of limit circles.

A limit circle is a circle with a diameter of the same length as the limit distance. That is, the limit circle has a radius of half the length of the limit distance.

The placement of limit circles is obtained by any method. For example, the placement of limit circles is obtained by a solution algorithm for a three-color problem.

In step S222, the number-of-allowable-users calculation unit 212 counts the number of limit circles that can be placed in the drawing of the room.

In step S223, the number-of-allowable-users calculation unit 212 generates available position data 295 based on the placement of limit circles.

The available position data 295 indicates the number of allowable users and available positions.

The number of allowable users corresponds to the number of limit circles that can be placed.

An available position is the position of the center of each of the limit circles that can be placed.

Referring back to FIG. 7, step S230 will be described.

In step S230, the result output unit 213 outputs the available position data 295.

For example, the result output unit 213 displays the number of allowable users and the available positions on a display.

### Features of Embodiment 2

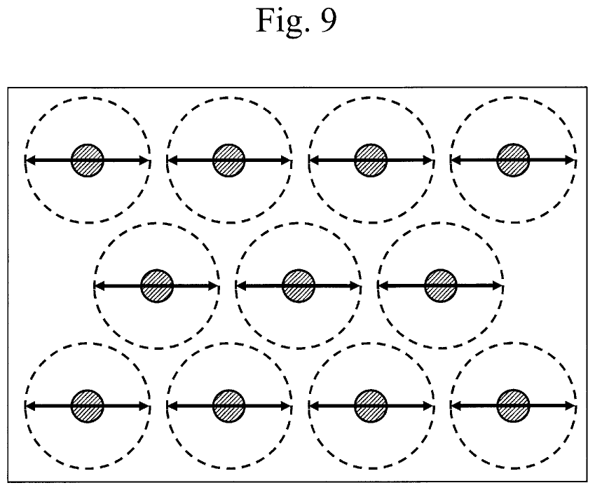

Based on FIG. 9, the features of Embodiment 2 will be described. A square frame represents a room. A double-headed arrow represents the limit distance. A dashed circle represents the limit circle. A shaded circle represents an available position.

The number-of-allowable-users calculation unit 212 places a plurality of limit circles in the drawing of the room so as to result in the maximum number of limit circles, on condition that there is no overlapping of limit circles. The center of each limit circle that can be placed is an available position.

### Effects of Embodiment 2

With Embodiment 2, the number of allowable users can be automatically calculated also for a room in which the positions of seats cannot be fixed.

### Embodiment 3

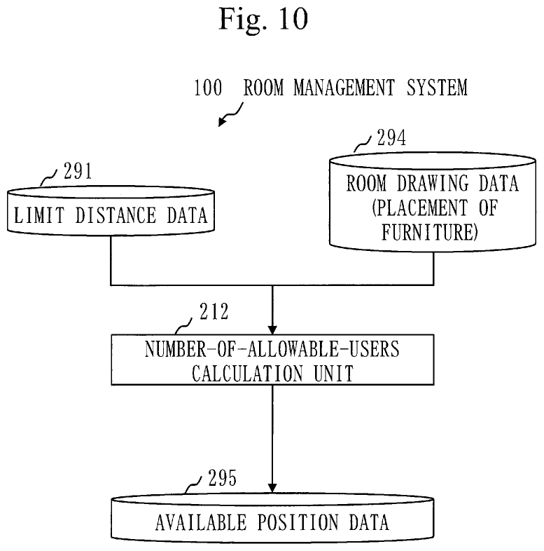

With regard to an embodiment in which furniture in a room is taken into consideration, differences from Embodiment 2 will be mainly described based on FIGS. 10 to 13.

### Description of Configuration

The configuration of the room management system 100 is the same as the configuration in Embodiment 2. However, the content of the room drawing data 294 is partially different from the content in Embodiment 2.

FIG. 10 illustrates a main functional configuration of the room management system 100.

The room drawing data 294 indicates the placement of furniture in the room in addition to information on the shape of the room, the size of the room, and so on. Specific examples of furniture are a desk and a partition.

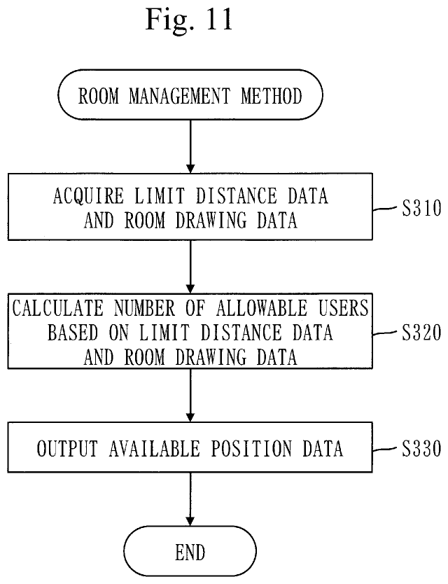

Based on FIG. 11, a room management method will be described.

In step S310, the data acquisition unit 211 acquires the limit distance data 291 and the room drawing data 294.

Step S310 is the same as step S210 in Embodiment 2.

In step S320, the number-of-allowable-users calculation unit 212 calculates the number of allowable users of the room based on the limit distance data 291 and the room drawing data 294.

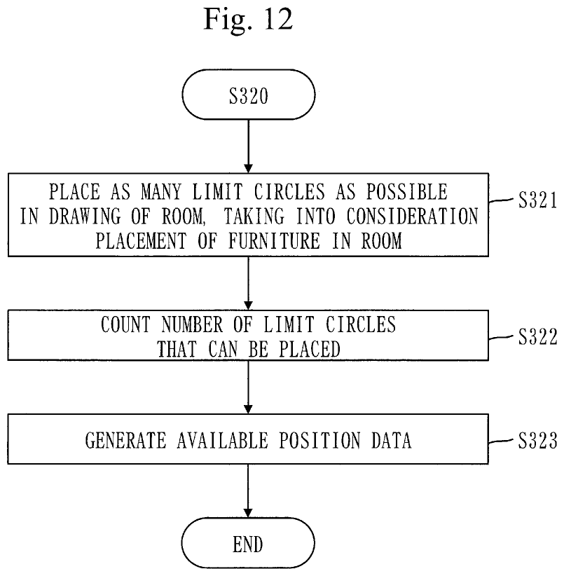

Based on FIG. 12, a procedure for step S320 will be described.

In step S321, the number-of-allowable-users calculation unit 212 places as many as limit circles as possible in the drawing of the room so as to avoid placing the center of each limit circle in the area of the furniture and avoid overlapping of limit circles.

In step S322, the number-of-allowable-users calculation unit 212 counts the number of limit circles that can be placed in the drawing of the room.

Step S322 is the same as step S222 in Embodiment 2.

In step S323, the number-of-allowable-users calculation unit 212 generates the available position data 295 based on the placement of limit circles.

Step S323 is the same as step S223 in Embodiment 2.

### Features of Embodiment 3

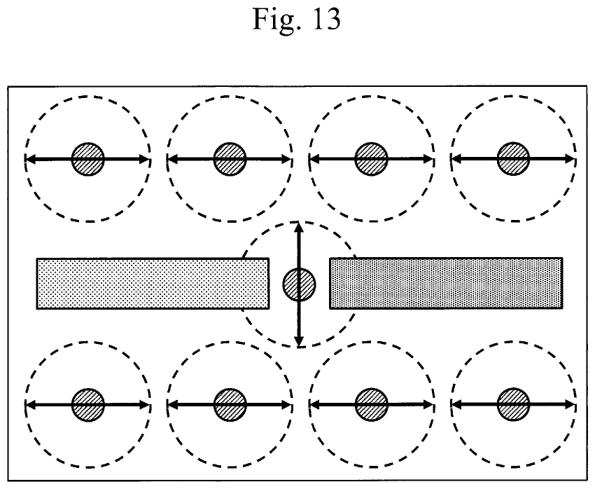

Based on FIG. 13, the features of Embodiment 3 will be described. A shaded square represents furniture.

The number-of-allowable-users calculation unit 212 places a plurality of limit circles in the drawing of the room so as to result in the maximum number of limit circles, on condition that there is no overlapping of limit circles and the center of each limit circle is not placed in the area of furniture. The center of each limit circle that can be placed is an available position.

### Embodiment 4

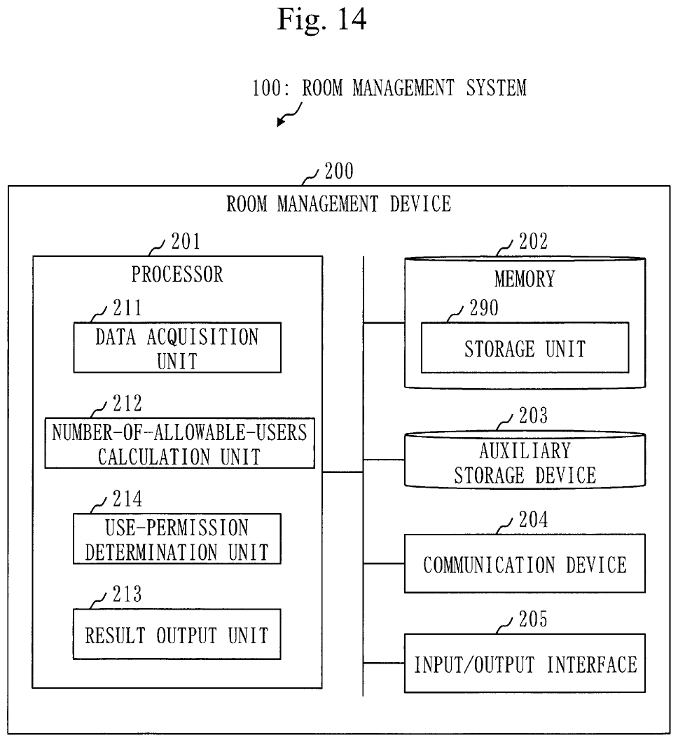

With regard to an embodiment in which whether or not to permit use of a room is determined based on the number of allowable users, differences from Embodiments 1 to 3 will be mainly described based on FIGS. 14 to 17.

### Description of Configuration

Based on FIG. 14, a configuration of the room management system 100 will be described.

The room management system 100 includes the room management device 200.

The room management device 200 further includes a use-permission determination unit 214.

The room management program further causes a computer to function as the use-permission determination unit 214.

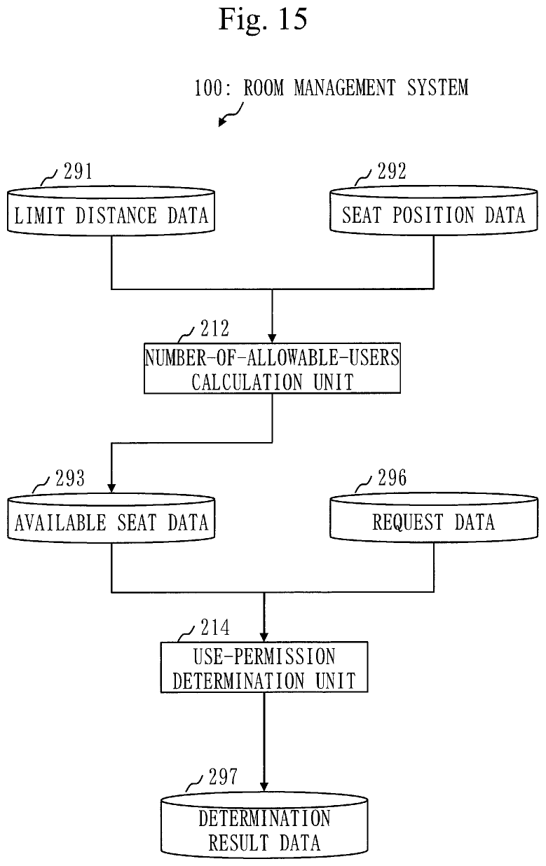

FIG. 15 illustrates a main functional configuration of the room management system 100.

The operation of each element and the content of each piece of data in the room management system 100 will be described later.

### Description of Operation

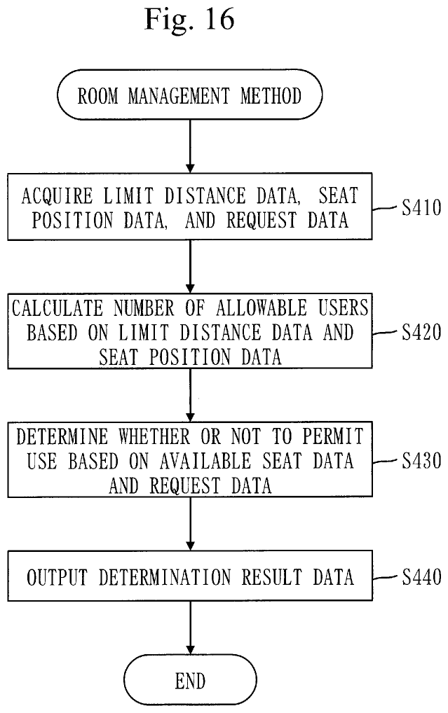

Based on FIG. 16, a room management method will be described.

In step S410, the data acquisition unit 211 acquires the limit distance data 291, the seat position data 292, and request data 296.

The request data 296 indicates information on one or more requesters.

A requester is a person who makes a request for using the room.

In step S420, the number-of-allowable-users calculation unit 212 calculates the number of allowable users of the room based on the limit distance data 291 and the room drawing data 294.

Step S420 is the same as step S120 in Embodiment 1.

By step S420, the available seat data 293 is obtained.

In step S430, the use-permission determination unit 214 determines whether each requester is permitted to use the room based on the available seat data 293 and the request data 296.

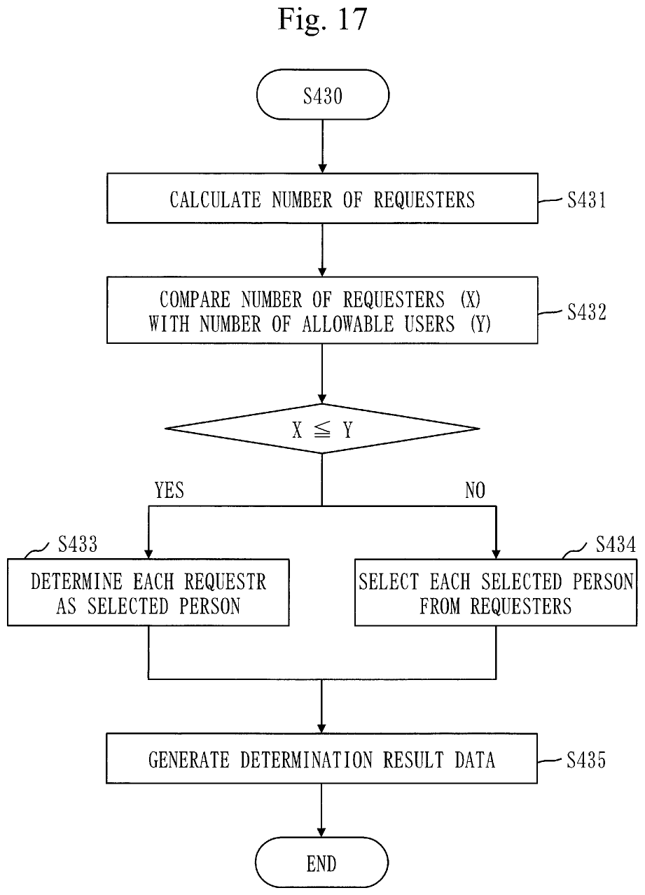

Based on FIG. 17, a procedure for step S430 will be described.

In step S431, the use-permission determination unit 214 refers to the request data 296 to calculate the number of requesters.

In step S432, the use-permission determination unit 214 compares the number of requesters with the number of allowable users.

If the number of requesters is equal to or smaller than the number of allowable users, processing proceeds to step S433.

If the number of requesters is greater than the number of allowable users, processing proceeds to step S434.

In step S433, the use-permission determination unit 214 determines every requester as a selected person.

A selected person is a requester who is permitted to use the room.

After step S433, processing proceeds to step S435.

In step S434, the use-permission determination unit 214 selects a requester or requesters fewer than or equal to the number of allowable users. Each selected requester is a selected person.

Each selected person is selected by any method. Each selected person may be selected on a first-come-first-served basis, may be selected at random, or may be selected based on the attribute of each selected person (for example, the title or belonging division of each employee).

After step S434, processing proceeds to step S435.

In step S435, the use-permission determination unit 214 generates determination result data 297 based on a result of determining each selected person.

The determination result data 297 indicates whether or not use of the room is permitted for each requester.

Referring back to FIG. 16, step S440 will be described.

In step S440, the result output unit 213 outputs the determination result data 297.

For example, the result output unit 213 notifies each requester indicated in the determination result data 297 whether or not use of the room is permitted. The notification is performed by any method. A specific example of the method of notification is an electronic mail.

### Effects of Embodiment 4

With Embodiment 4, whether or not to permit use of a room can be determined for each requester so that an appropriate distance can be kept between persons in the room.

For example, if the number of employees requesting to work in the office reaches the number of allowable users of the room, the use-permission determination unit 214 restricts working in the office for employees newly requesting to work in the office. This allows an appropriate distance to be kept between employees.

### Implementation Example of Embodiment 4

In Embodiment 4, the number-of-allowable-users calculation unit 212 may calculate the number of allowable users by the method in Embodiment 2 or the method in Embodiment 3.

### Embodiment 5

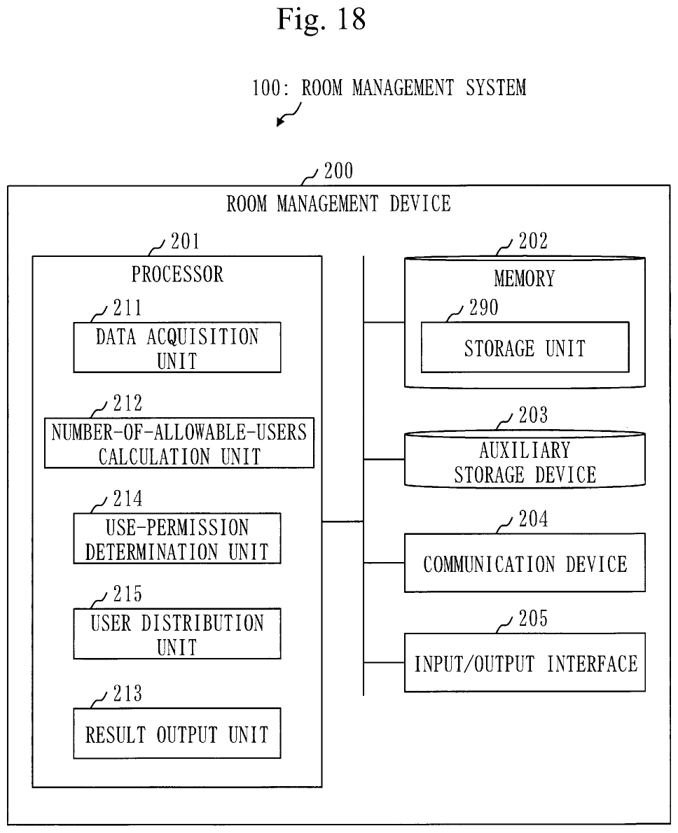

With regard to an embodiment in which persons are distributed to a plurality of rooms, differences from Embodiment 4 will be mainly described based on FIGS. 18 to 22.

### Description of Configuration

Based on FIG. 18, a configuration of the room management system 100 will be described.

The room management system 100 includes the room management device 200.

The room management device 200 further includes a user distribution unit 215.

The room management program further causes a computer to function as the user distribution unit 215.

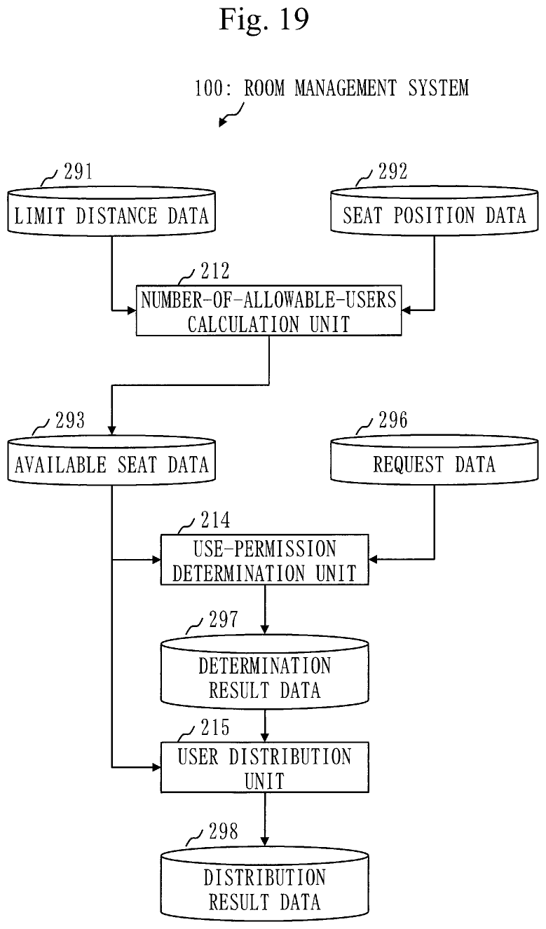

FIG. 19 illustrates a main functional configuration of the room management system 100.

The operation of each element and the content of each piece of data in the room management system 100 will be described later.

### Description of Operation

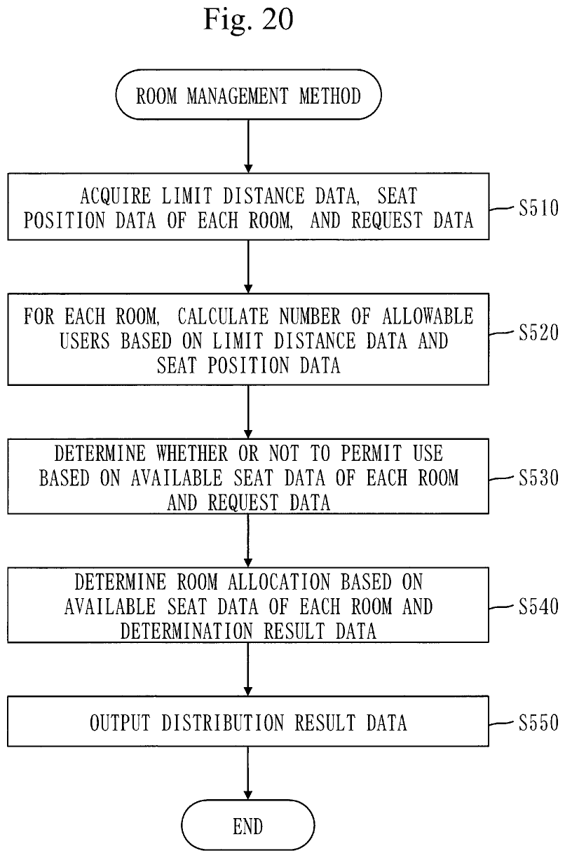

Based on FIG. 20, a room management method will be described.

In step S510, the data acquisition unit 211 acquires the limit distance data 291, the seat position data 292 of each room, and the request data 296.

In step S520, the number-of-allowable-users calculation unit 212 calculates, for each room, the number of allowable users based on the limit distance data 291 and the seat position data 292.

The method of calculation is the same as the method in step S120 in Embodiment 1.

By step S520, the available seat data 293 is obtained for each room.

In step S530, the use-permission determination unit 214 determines whether or not to permit use of the room for each requester based on the available seat data 293 of each room and the request data 296.

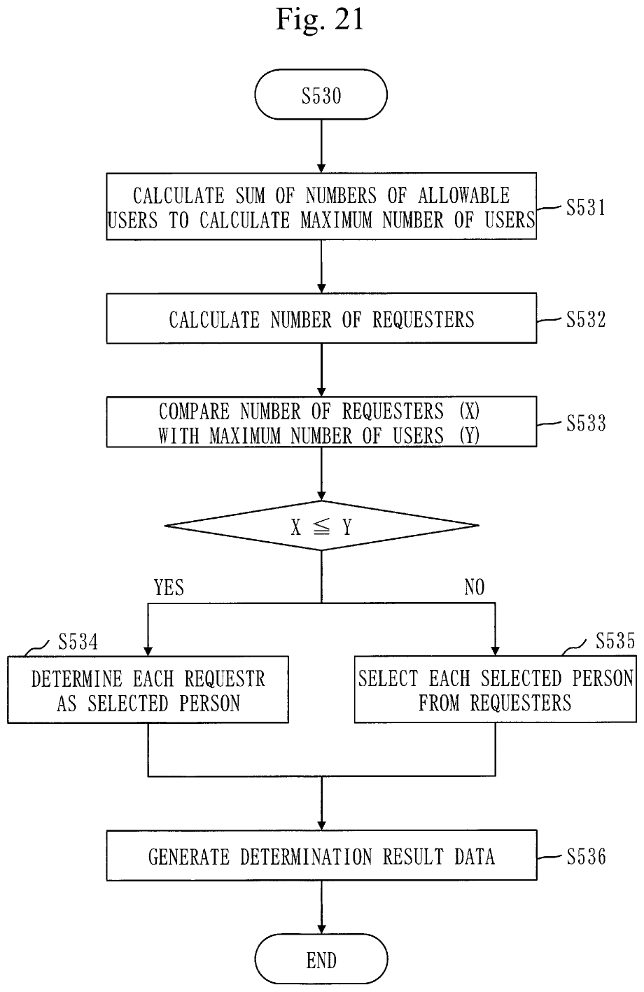

Based on FIG. 21, a procedure for step S530 will be described.

In step S531, the use-permission determination unit 214 calculates the sum of the numbers of allowable users of the individual rooms. The number of persons obtained by this will be referred to as the “maximum number of users.

In step S532, the use-permission determination unit 214 refers to the request data 296 to calculate the number of requesters.

In step S533, the use-permission determination unit 214 compares the number of requesters with the maximum number of users.

If the number of requesters is equal to or smaller than the maximum number of users, processing proceeds to step S534.

If the number of requesters is greater than the maximum number of users, processing proceeds to step S535.

In step S534, the use-permission determination unit 214 determines every requester as a selected person.

After step S534, processing proceeds to step S536.

In step S535, the use-permission determination unit 214 selects a requester or requesters equal to or less than the maximum number of users. Each selected requester is a selected person.

After step S535, processing proceeds to step S536.

In step S536, the use-permission determination unit 214 generates determination result data 297 based on a result of determining each selected person.

Referring back to FIG. 20, the description will be continued from step S540. In step S540, the user distribution unit 215 determines room allocation based on the determination result data 297 and the available seat data 293 of each room.

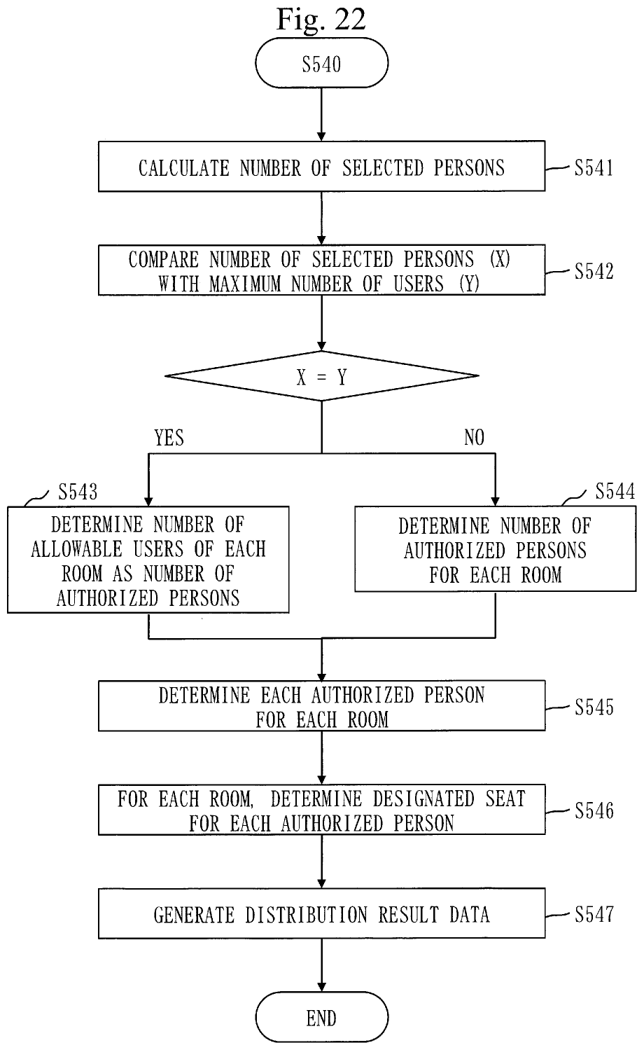

Based on FIG. 22, a procedure for step S540 will be described.

In step S541, the user distribution unit 215 refers to the determination result data 297 to calculate the number of selected persons.

In step S542, the user distribution unit 215 compares the number of selected persons with the maximum number of users. Note that the number of selected persons is equal to or smaller than the maximum number of users.

If the number of selected persons is equal to the maximum number of users, processing proceeds to step S543.

If the number of selected persons is smaller than the maximum number of users, processing proceeds to step S544.

In step S543, the user distribution unit 215 determines the number of allowable users of each room as the number of authorized persons.

The number of authorized persons is the number of selected persons permitted to use the room (authorized persons).

After step S543, processing proceeds to step S545.

In step S544, the user distribution unit 215 determines, for each room, the number of authorized persons equal to or smaller than the number of allowable users.

Specifically, the user distribution unit 215 determines the number of authorized persons for each room so that the authorized persons are distributed evenly to each room.

After step S544, processing proceeds to step S545.

In step S545, the user distribution unit 215 determines, as authorized persons, the same number of selected persons as the number of authorized persons, for each room.

The authorized persons of each room are determined by any method. The authorized persons of each room may be determined at random, or may be determined based on the attributes of selected persons.

In step S546, the user distribution unit 215 determines a designated seat for each authorized person from among the seats indicated in the available seat data 293, for each room.

A designated seat is a seat assigned to an authorized person.

The designated seat is determined by any method. For example, the designated seat is determined at random.

In step S547, the user distribution unit 215 generates distribution result data 298 based on a result of determining the designated seat for each authorized person.

The distribution result data 298 indicates the designated seat of each authorized person.

Referring back to FIG. 20, step S550 will be described.

In step S550, the result output unit 213 outputs the distribution result data 298.

For example, the result output unit 213 notifies each authorized person of the designated seat.

### Effects of Embodiment 5

With Embodiment 5, persons can be distributed to rooms and floors. This reduces chances of contact between persons and reduces the risk of infection.

For example, if there are fewer employees coming to work in the office than the number of available seats, the user distribution unit 215 determines a seat for each employee so that each room and each floor has approximately the same number of persons. This prevents employees from being concentrated in a specific room.

### Implementation Examples of Embodiment 5

In Embodiment 5, the user distribution unit 215 may omit determining a designated seat for each authorized person.

In Embodiment 5, the number-of-allowable-users calculation unit 212 may calculate the number of allowable users by the method in Embodiment 2 or the method in Embodiment 3.

### Embodiment 6

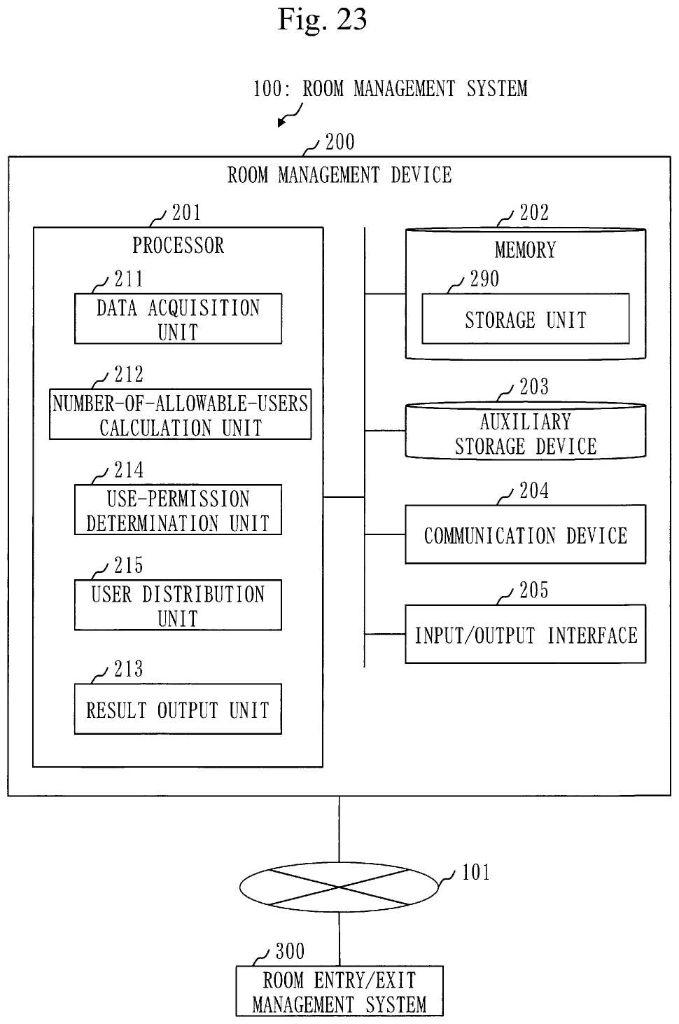

With regard to an embodiment in which access control is performed based on room allocation, differences from Embodiment 5 will be mainly described based on FIGS. 23 to 26.

### Description of Configuration

Based on FIG. 23, a configuration of the room management system 100 will be described.

The room management system 100 includes the room management device 200 and an access control system 300.

The room management device 200 communicates with the access control system 300 via a network 101.

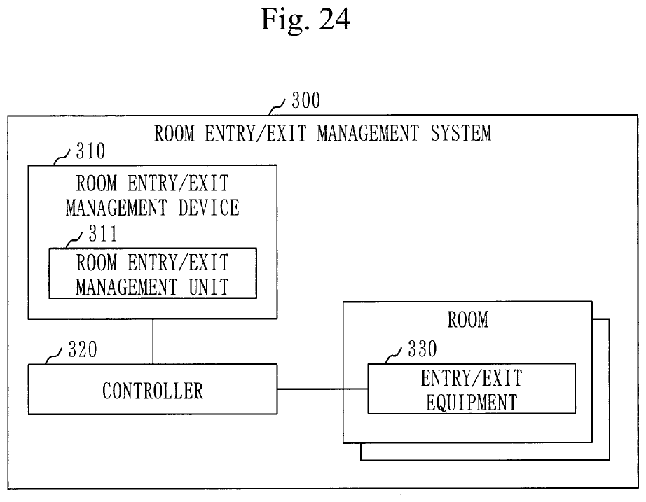

Based on FIG. 24, a configuration of the access control system 300 will be described.

The access control system 300 includes an access control device 310 and a controller 320. The access control system 300 also includes access control equipment 330 in each room.

The access control device 310 is a computer that functions as an access control unit 311.

The controller 320 is a computer that controls the access control equipment 330 of each room.

The access control equipment 330 is equipment to restrict enter and leave the room. A specific example of the access control equipment 330 is a card reader and an electric lock.

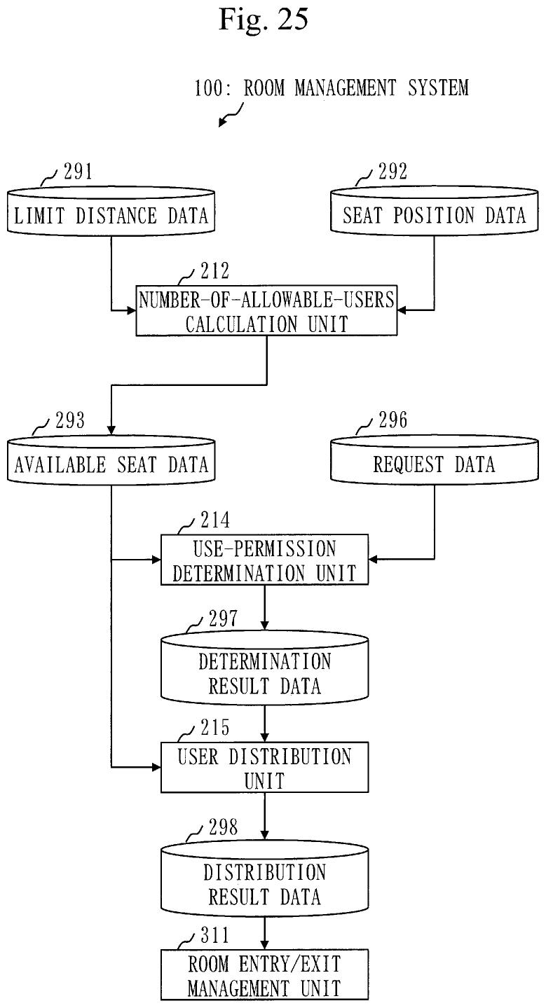

FIG. 25 illustrates a main functional configuration of the room management system 100.

The operation of each element and the content of each piece of data in the room management system 100 will be described later.

### Description of Operation

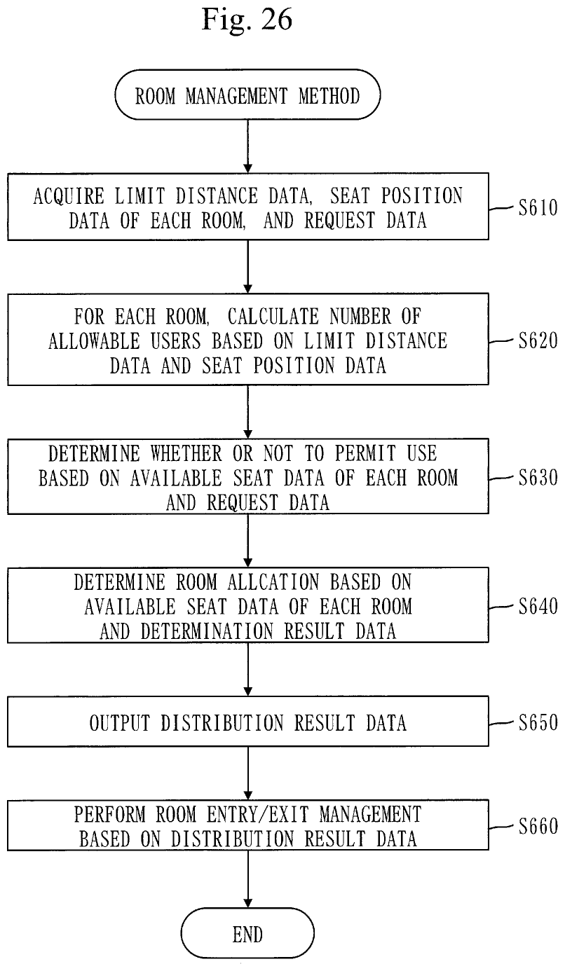

Based on FIG. 26, a room management method will be described.

Step S610 to step S640 are the same as step S510 to step S540 in Embodiment 5.

In step S650, the result output unit 213 outputs the distribution result data 298.

Specifically, the result output unit 213 transmits the distribution result data 298 to the access control system 300. In the access control system 300, the access control unit 311 receives the distribution result data 298.

In step S660, the access control unit 311 performs access control based on the distribution result data 298.

Specifically, the access control unit 311 restricts enter the room only to the authorized persons of the room.

The access control is performed as described below.

The controller 320 detects a user access to the access control equipment 330 of the room. For example, a user places an authentication card on the card reader, and the controller 320 detects reading of the authentication card by the card reader.

The controller 320 transmits access information of the user to the access control device 310. For example, the controller 320 transmits information that identifies the access control equipment 330 and information that is read out from the authentication card to the access control device 310.

The access control unit 311 determines whether the user is the authorized person of the room based on the distribution result data 298 and the access information, and transmits a result of determination to the controller 320.

If the user is the authorized person of the room, the controller 320 controls the access control equipment 330 of the room to permit the user enter the room. For example, the controller 320 unlocks the electric lock of the room.

If the user is not the authorized person of the room, the controller 320 controls the access control equipment 330 of the room to refuse the user enter the room. For example, the controller 320 keeps the electric lock of the room locked without unlocking it.

### Effects of Embodiment 6

With Embodiment 6, it is possible to restrict movement of a person to a room (or floor) where the person has no designated seat that is assigned. This reduces chances of contact between persons and reduces the risk of infection.

For example, the access control unit 311 permits each employee enter a room where the employee has a designated seat, but refuses each employee enter a room where the employee has no designated seat. This can reduce contact between employees who work in different rooms.

### Embodiment 7

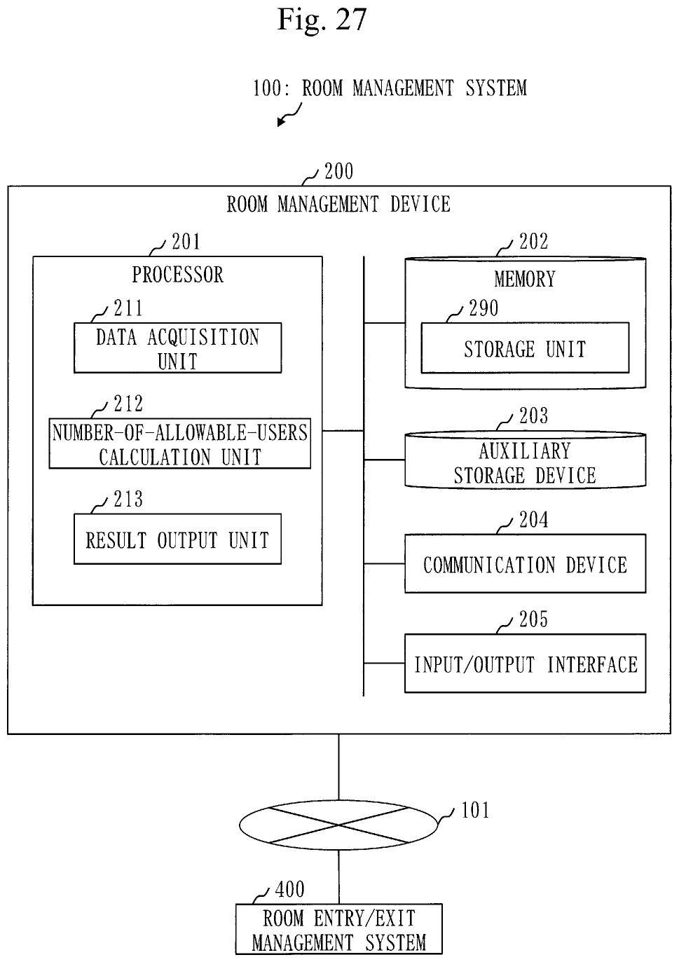

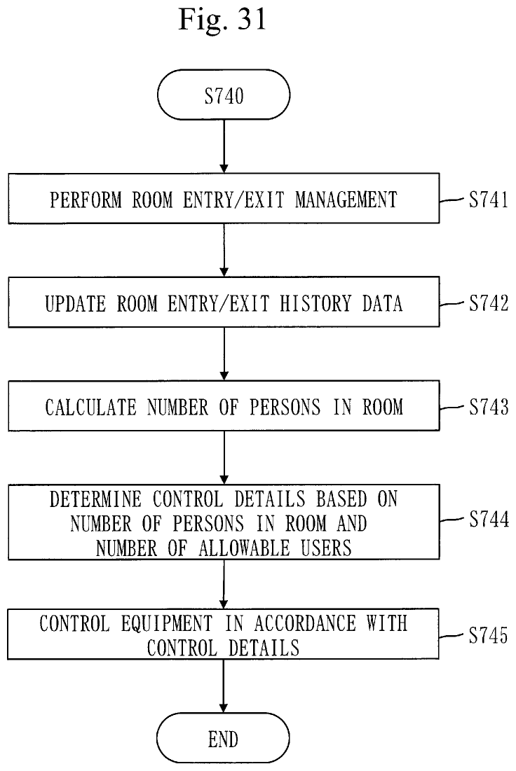

With regard to an embodiment in which equipment in a room is controlled, differences from Embodiment 1 will be mainly described based on FIGS. 27 to 31.

### Description of Configuration

Based on FIG. 27, a configuration of the room management system 100 will be described.

The room management system 100 includes the room management device 200 and an access control system 400.

The room management device 200 communicates with the access control system 400 via the network 101.

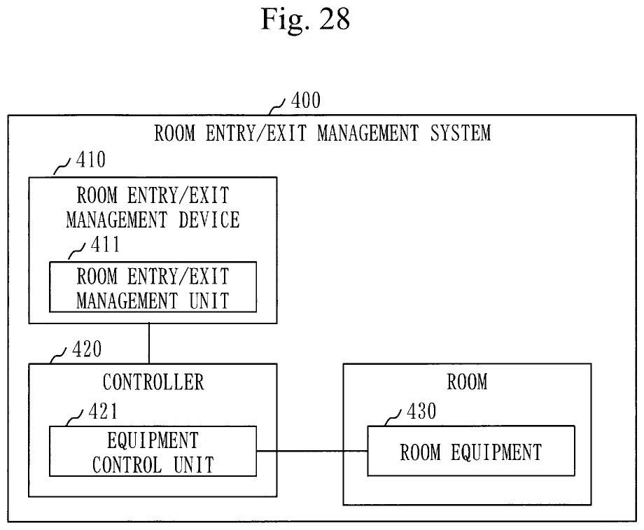

Based on FIG. 28, a configuration of the access control system 400 will be described.

The access control system 400 includes an access control device 410, a controller 420, and room equipment 430.

The access control device 410 is a computer that functions as an access control unit 411.

The controller 420 is a computer that functions as an equipment control unit 421.

The room equipment 430 is equipment installed in the room. Specific examples of the room equipment 430 are access control equipment and ventilation equipment. A specific example of the access control equipment is a card reader and an electric lock. Specific examples of the ventilation equipment are an air conditioner and a ventilation fan.

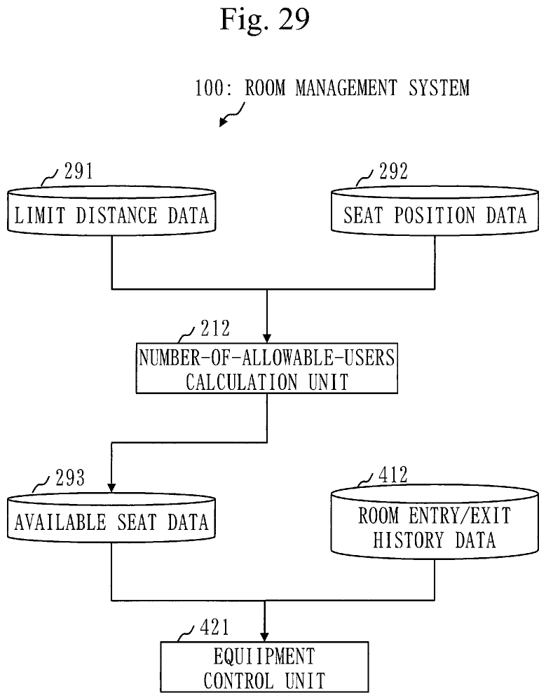

FIG. 29 illustrates a main functional configuration of the room management system 100.

The operation of each element and the content of each piece of data in the room management system 100 will be described later.

### Description of Operation

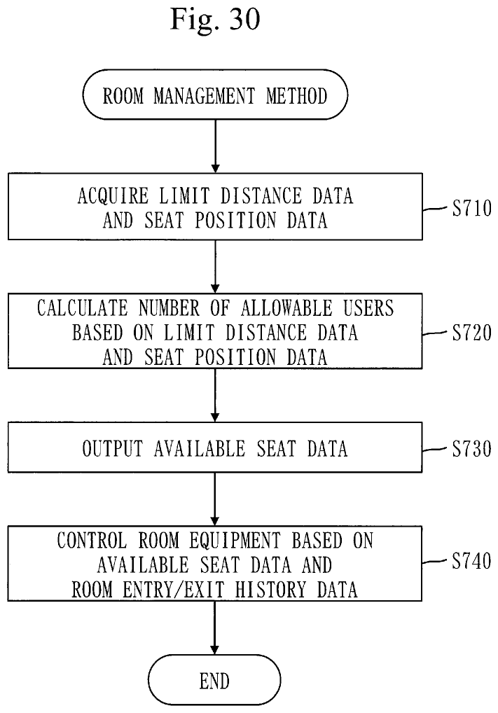

Based on FIG. 30, a room management method will be described.

Step S710 and step S720 are the same as step S110 and step S120 in Embodiment 1.

In step S730, the result output unit 213 outputs the available seat data 293.

Specifically, the result output unit 213 transmits the available seat data 293 to the access control system 400. In the access control system 400, the access control unit 411 receives the available seat data 293.

In step S740, the equipment control unit 421 controls the room equipment 430 based on the available seat data 293 and access control history data 412.

In step S741, the access control unit 411 performs access control. That is, the access control unit 411 performs user authentication, and permits a proper user enter and leave the room and refuses an improper user enter and leave the room.

In step S742, the access control unit 411 updates the access control history data 412.

The access control history data 412 indicates an access control history of each user.

In step S743, the equipment control unit 421 refers to the access control history data 412 to calculate the number of persons in the room.

In step S744, the equipment control unit 421 determines control details for the room equipment 430 based on the number of persons in the room and the number of allowable users.

For example, if the number of persons in the room is greater than the number of allowable users, the equipment control unit 421 controls the access control equipment to refuse a new user enter the room.

For example, the equipment control unit 421 controls the ventilation equipment so that the greater the ratio of the number of persons in the room to the number of allowable users, the greater the ventilation volume.

In step S745, the equipment control unit 421 controls the room equipment 430 in accordance with the control details.

### Effects of Embodiment 7

With Embodiment 7, the room equipment 430 can be controlled according to the number of persons in the room. This reduces chances of contact between persons, resolves a lack of ventilation, and reduces the risk of infection.

### Implementation Example of Embodiment 7

In Embodiment 7, the number-of-allowable-users calculation unit 212 may calculate the number of allowable users by the method in Embodiment 2 or the method in Embodiment 3.

### Embodiment 8

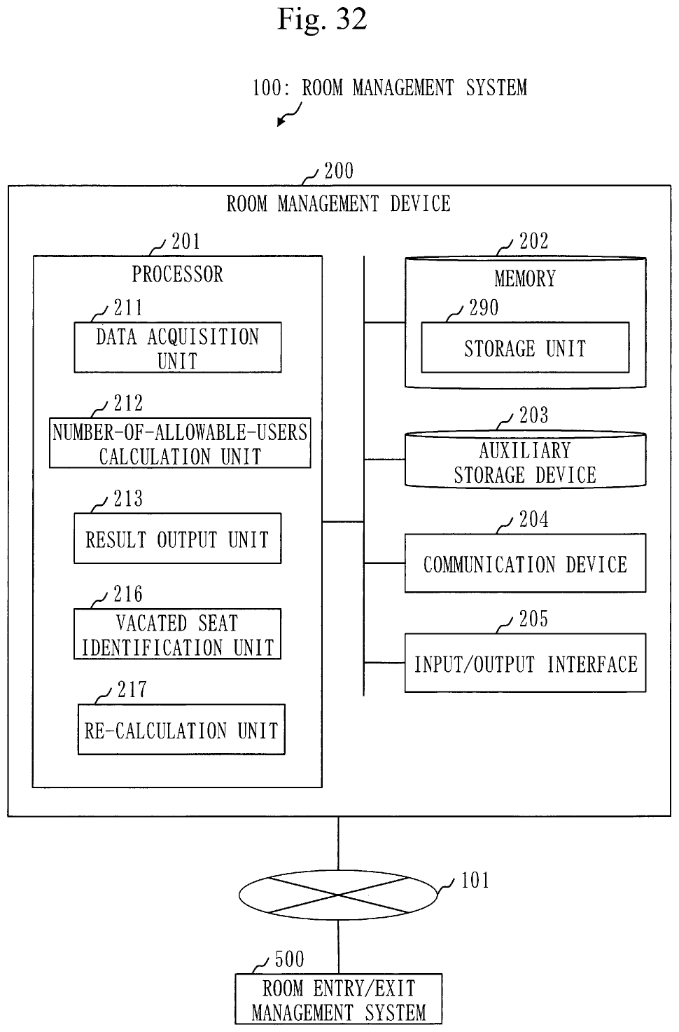

With regard to an embodiment in which the number of allowable users is re-calculated when a user has left the room, differences from Embodiment 1 will be mainly described based on FIGS. 32 to 36.

### Description of Configuration

Based on FIG. 32, a configuration of the room management system 100 will be described.

The room management system 100 includes the room management device 200 and an access control system 500.

The room management device 200 communicates with the access control system 500 via the network 101.

The room management device 200 further includes a vacated seat identification unit 216 and a re-calculation unit 217.

The room management program further causes a computer to function as the vacated seat identification unit 216 and the re-calculation unit 217.

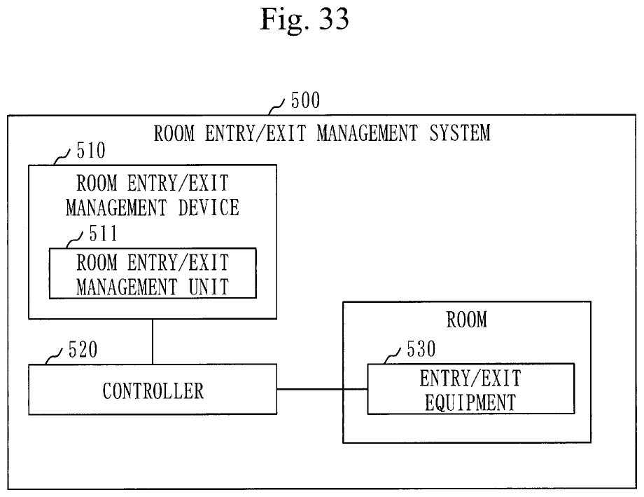

FIG. 33 illustrates a configuration of the access control system 500.

The access control system 500 includes an access control device 510, a controller 520, and access control equipment 530.

The access control device 510 is a computer that functions as an access control unit 511.

The controller 520 is a computer that controls the access control equipment 530.

The access control equipment 530 is equipment to control enter and leave the room. A specific example of the access control equipment 530 is a card reader and an electric lock.

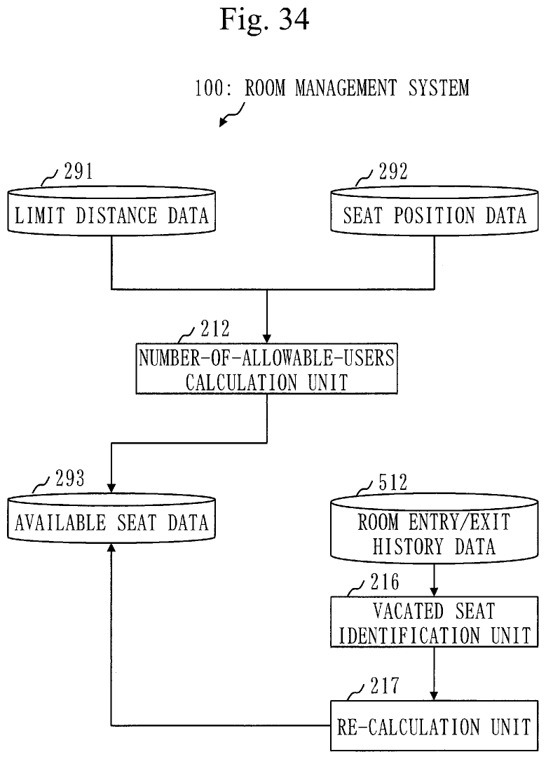

FIG. 34 illustrates a main functional configuration of the room management system 100.

The operation of each element and the content of each piece of data in the room management system 100 will be described later.

### Description of Operation

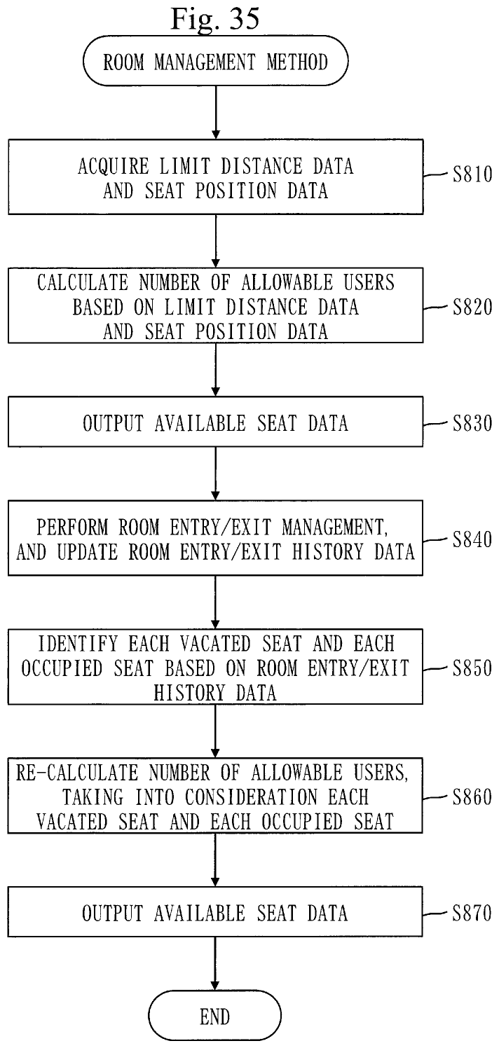

Based on FIG. 35, a room management method will be described.

Step S810 to step S830 are the same as step S110 to step S130 in Embodiment 1.

In step S840, the access control unit 511 performs access control. That is, the access control unit 511 performs user authentication, and permits a proper user enter and leave the room and refuses an improper user enter and leave the room.

Then, the access control unit 411 updates access control history data 512.

The access control history data 512 indicates an access control history of each user.

In step S850, the vacated seat identification unit 216 acquires the access control history data 512. Specifically, the vacated seat identification unit 216 receives the access control history data 512 by communicating with the access control management device 510.

Then, the vacated seat identification unit 216 identifies each vacated seat based on the access control history data 512.

A vacated seat is a seat that has been used by a person who has left the room.

For example, a card reader is provided at each seat, and a user places an authentication card on the card reader of the seat to be used. The access control unit 511 refers to information that is read by the card reader, and records information on the seat used by the user in the access control history data 512. Then, the vacated seat identification unit 216 refers to the access control history data 512 and identifies the vacated seat.

For example, a designated seat is determined for each user, as in Embodiment 5. Then, the vacated seat identification unit 216 refers to the access control history data 512 to identify the person who has left the room, and treats the designated seat of the person who has left the room as the vacated seat.

Similarly, the vacated seat identification unit 216 identifies each occupied seat.

An occupied seat is a seat being used.

In step S860, the re-calculation unit 217 re-calculates the number of allowable users, taking into consideration each vacated seat and each occupied seat.

Specifically, the re-calculation unit 217 calculates the number of allowable users by treating each vacated seat and each occupied seat as a seat that cannot be used.

Step S860 in the same as step S120 in Embodiment 1, except for the condition that each vacated seat and each occupied seat be treated as a seat that cannot be used.

In step S870, the result output unit 213 outputs the available seat data 293.

### Features of Embodiment 8

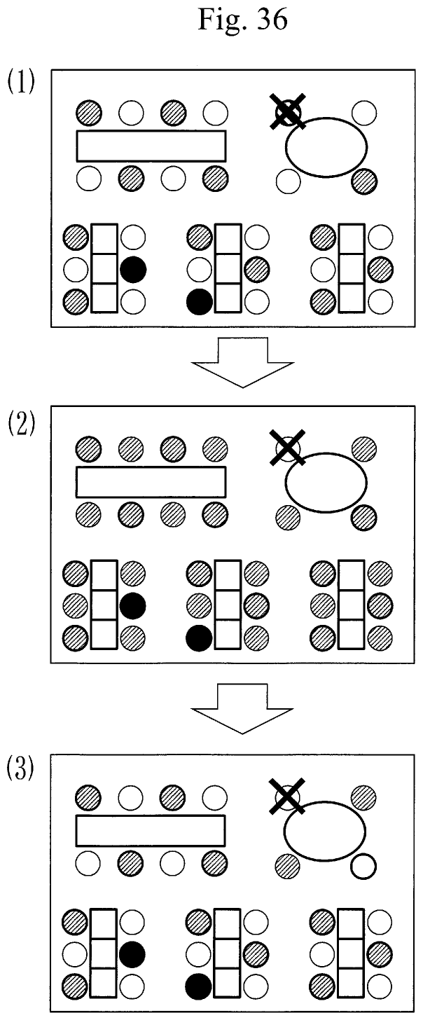

Based on FIG. 36, the features of Embodiment 8 will be described. A cross mark represents a vacated seat. A filled circle represents an occupied seat.

(1) The vacated seat identification unit 216 identifies each vacated seat and each occupied seat.

(2) The re-calculation unit 217 treats each vacated seat and each occupied seat as unavailable, and treats the remaining seats as available, and obtains the largest seat group.

(3) The re-calculation unit 217 calculates the number of seats of the largest seat group as the number of allowable users.

### Effects of Embodiment 8

With Embodiment 8, the number of allowable users can be re-calculated when a user has left the room by treating the vacated seat as unavailable until cleaning of the vacated seat completes. This allows the optimum number of allowable users to be always obtained.

### Implementation Example of Embodiment 8

In Embodiment 8, the number-of-allowable-users calculation unit 212 and the re-calculation unit 217 may calculate the number of allowable users by the method in Embodiment 2 or the method in Embodiment 3.

### Supplement to Embodiments

By applying each of the embodiments to a company, it is possible to calculate the number of allowable users that allows employees to work without coming into contact with each other. Furthermore, based on the number of allowable users, work attendance of employees can be restricted and equipment in the room can be controlled. This makes it possible to both prevent the spread of infection and continue business.

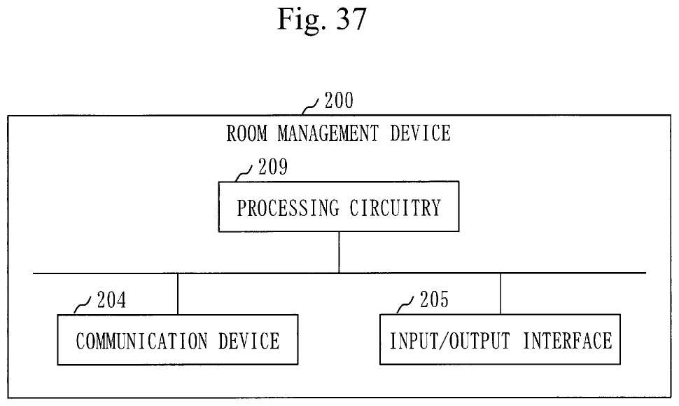

Based on FIG. 37, a hardware configuration of the room management device 200 will be described.

The room management device 200 includes processing circuitry 209.

The processing circuitry 209 is hardware that realizes the data acquisition unit 211, the number-of-allowable-users calculation unit 212, the result output unit 213, the use-permission determination unit 214, the user distribution unit 215, the vacated seat identification unit 216, and the re-calculation unit 217.

The processing circuitry 209 may be dedicated hardware, or may be the processor 201 that executes programs stored in the memory 202.

When the processing circuitry 209 is dedicated hardware, the processing circuitry 209 is, for example, a single circuit, a composite circuit, a programmed processor, a parallel-programmed processor, an ASIC, an FPGA, or a combination of these.

ASIC is an abbreviation for application specific integrated circuit.

FPGA is an abbreviation for field programmable gate array.

The room management device 200 may include a plurality of processing circuits as an alternative to the processing circuitry 209.

In the processing circuitry 209, some functions may be realized by dedicated hardware, and the remaining functions may be realized by software or firmware.

As described above, the functions of the room management device 200 can be realized by hardware, software, firmware, or a combination of these.

In the access control system in each of the embodiments, each of the access control device and the controller also includes processing circuitry similarly.

Each of the embodiments is an example of a preferred embodiment and is not intended to limit the technical scope of the present disclosure. Each of the embodiments may be implemented partially or may be implemented in combination with another embodiment. The procedures described using the flowcharts or the like may be changed as appropriate.

Each “unit” that is an element of the room management system 100 may be interpreted as “process”, “step”, “circuit”, or “circuitry”.

### REFERENCE SIGNS LIST

100: room management system, 101: network, 200: room management device, 201: processor, 202: memory, 203: auxiliary storage device, 204: communication device, 205: input/output interface, 209: processing circuitry, 211: data acquisition unit, 212: number-of-allowable-users calculation unit, 213: result output unit, 214: use-permission determination unit, 215: user distribution unit, 216: vacated seat identification unit, 217: re-calculation unit, 290: storage unit, 291: limit distance data, 292: seat position data, 293: available seat data, 294: room drawing data, 295: available position data, 296: request data, 297: determination result data, 298: distribution result data, 300: access control system, 310: access control device, 311: access control unit, 320: controller, 330: access control equipment, 400: access control system, 410: access control device, 411: access control unit, 412: access control history data, 420: controller, 421: equipment control unit, 430: room equipment, 500: access control system, 510: access control device, 511: access control unit, 512: access control history data, 520: controller, 530: access control equipment.

1. A room management system comprising processing circuitry to calculate, as the number of allowable users of a room, the number of persons with which a distance equal to or greater than a limit distance can be secured in the room, based on limit distance data indicating the limit distance defined as a distance to be kept between persons and room data indicating information on the room to be used by one or more persons.

2. The room management system according to claim 1,
wherein the room data is seat position data indicating positions of a plurality of seats in the room, and
wherein the processing circuitry calculates a distance between seats for each pair of seats in the room based on the positions of the plurality of seats indicated in the seat position data,
counts the number of seats for each seat group composed of two or more seats between which a distance equal to or greater than the limit distance is secured, based on the calculated distances between seats, and
obtains, as the number of allowable users, the number of seats in a seat group with the maximum number of seats.

3. The room management system according to claim 1,
wherein the room data is drawing data indicating a drawing of the room, and
wherein the processing circuitry places as many limit circles as possible in the drawing of the room indicated in the drawing data so as to avoid overlapping of limit circles, each of the limit circles having a diameter of a same length as the limit distance, and
counts, as the number of allowable users, the number of limit circles that can be placed.

4. The room management system according to claim 3,
wherein the drawing data indicates placement of furniture in the room, and
wherein the processing circuitry places as many limit circles as possible in the drawing of the room so as to avoid placing a center of each limit circle in an area of the furniture and avoid overlapping of limit circles.

5. The room management system according to claim 1,
wherein the processing circuitry refers to request data indicating information on one or more requesters who wish to use the room so as to calculate the number of requesters, compares the number of requesters with the number of allowable users, and determines whether or not to permit each requester to use the room based on a result of comparison.

6. The room management system according to claim 1,
wherein the processing circuitry calculates the number of allowable users for each of a plurality of rooms,
wherein based on request data indicating information on one or more requesters who wish to use the room, the processing circuitry determines, as selected persons to be permitted to use the room, requesters equal to or fewer than the maximum number of users obtained by calculating a sum of the numbers of allowable users, and
wherein the processing circuitry determines, for each room, the number of persons to be permitted to use the room as the number of authorized persons, based on the number of selected persons and the number of allowable users of each room, and determines, for each room, the same number of selected persons as the number of authorized persons each as an authorized person.

7. The room management system according to claim 6,
wherein the processing circuitry restricts, for each of the plurality of rooms, enter the room only to the authorized person of the room.

8. The room management system according to claim 1,
wherein the processing circuitry refers to access control history data indicating a history of enter and leave the room so as to calculate the number of persons in the room, determines control details for equipment in the room based on the number of persons in the room and the number of allowable users, and controls the equipment in accordance with the control details.

9. The room management system according to claim 1,
wherein the processing circuitry refers to access control history data indicating a history of enter and leave the room so as to identify, as a vacated seat, a seat used by a person who has left the room, and
re-calculates the number of allowable users by treating the vacated seat as a seat that cannot be used.

10. A room management method comprising
calculating, as the number of allowable users of a room, the number of persons with which a distance equal to or greater than a limit distance can be secured in the room, based on limit distance data indicating the limit distance defined as a distance to be kept between persons and room data indicating information on the room to be used by one or more persons.

11. Anon-transitory computer readable medium storing a room management program to cause a computer to execute
a number-of-allowable-users calculation process of calculating, as the number of allowable users of a room, the number of persons with which a distance equal to or greater than a limit distance can be secured in the room, based on limit distance data indicating the limit distance defined as a distance to be kept between persons and room data indicating information on the room to be used by one or more persons.
